(19) United States
(12) Patent Application Publication
(10) Pub. No.: US 2025/0210493 A1
(43) Pub. Date: Jun. 26, 2025

(54) SEMICONDUCTOR DEVICE

(71) Applicants: KABUSHIKI KAISHA TOSHIBA, Tokyo (JP); TOSHIBA ELECTRONIC DEVICES & STORAGE CORPORATION, Tokyo (JP)

(72) Inventor: Fumiyoshi KAWASHIRO, Chiyoda Tokyo (JP)

(21) Appl. No.: 19/073,523

(22) Filed: Mar. 7, 2025

Related U.S. Application Data
(63) Continuation of application No. PCT/JP2024/006440, filed on Feb. 22, 2024.

(30) Foreign Application Priority Data
Jul. 31, 2023 (JP) 2023-125137

(51) Int. Cl. H01L 23/498; H01L 23/00; H01L 23/31

(52) U.S. Cl. CPC H01L 23/49833; H01L 24/32; H01L 24/48; H01L 24/73; H01L 23/3107; H01L 2224/32225; H01L 2224/48227; H01L 2224/73265

(57) ABSTRACT

A semiconductor device according to an embodiment includes a first insulating plate, a first metal plate provided on a first surface of the first insulating plate, a second metal plate provided on a second surface of the first insulating plate opposite the first surface, a semiconductor chip provided on the second metal plate, and a resin member encapsulating the semiconductor chip. In this semiconductor device, the number of semiconductor chips provided on the second metal plate is only one.

### CROSS-REFERENCE TO RELATED APPLICATIONS

This application is based upon and claims the benefit of priority from Japanese Patent Application No. 2023-125137, filed on Jul. 31, 2023 and PCT Application No. PCT/JP2024/006440, filed on Feb. 22, 2024; the entire contents of which are incorporated herein by reference.

### FIELD

The embodiments of the present invention relate to a semiconductor device.

### BACKGROUND

In a high-voltage power module used in an electric vehicle or the like, a semiconductor chip such as a MOSFET (Metal Oxide Semiconductor Field Effect Transistor) and an IGBT (Insulated Gate Bipolar Transistor) is mounted on an insulating plate. Since many semiconductor chips are generally used in such a power module, improvement of the yield is demanded.

### BRIEF DESCRIPTION OF THE DRAWINGS

FIG. 1 is a cross-sectional view illustrating a schematic configuration of a semiconductor device according to a first embodiment;

FIG. 2 is a cross-sectional view illustrating a schematic configuration of a semiconductor device according to a second embodiment;

FIG. 3 is a cross-sectional view illustrating a schematic configuration of a semiconductor device according to a modification of the second embodiment;

FIG. 4 is a cross-sectional view illustrating a schematic configuration of a semiconductor device according to a third embodiment;

FIG. 5 is a cross-sectional view illustrating a schematic configuration of a semiconductor device according to a fourth embodiment;

FIG. 6 is a cross-sectional view illustrating a schematic configuration of a semiconductor device according to a fifth embodiment;

FIG. 7 is a cross-sectional view illustrating a disassembled configuration of a semiconductor device according to a sixth embodiment; and

FIG. 8 is a cross-sectional view illustrating a schematic configuration of the semiconductor device according to the sixth embodiment.

### DETAILED DESCRIPTION

Embodiments will now be explained with reference to the accompanying drawings. The present invention is not limited to the embodiments.

A semiconductor device according to an embodiment includes a first insulating plate, a first metal plate provided on a first surface of the first insulating plate, a second metal plate provided on a second surface of the first insulating plate opposite the first surface, a semiconductor chip provided on the second metal plate, and a resin member encapsulating the semiconductor chip. In this semiconductor device, the number of semiconductor chips provided on the second metal plate is only one.

### First Embodiment

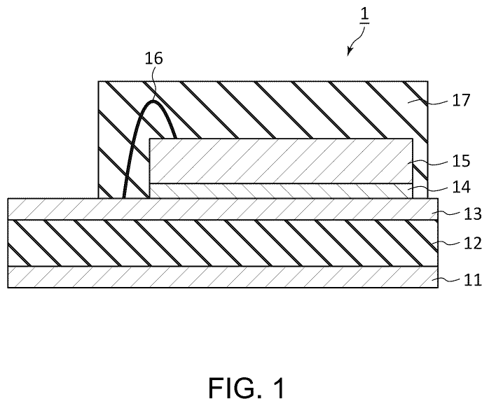

FIG. 1 is a cross-sectional view illustrating a schematic configuration of a semiconductor device according to a first embodiment. A semiconductor device 1 illustrated in FIG. 1 includes a first metal plate 11, a first insulating plate 12, a second metal plate 13, a first joining material 14, a semiconductor chip 15, a bonding wire 16, and a resin member 17.

The first metal plate 11 is joined to the back surface (first surface) of the first insulating plate 12. The first metal plate 11 functions as a heat-dissipation plate dissipating heat generated by an operation of the semiconductor chip 15. The first metal plate 11 can be formed by processing copper (Cu) into a plate shape, for example.

The first insulating plate 12 contains an insulating material such as silicon nitride (SiN), aluminum nitride (AlN), and aluminum oxide (Al₂O₃). The first insulating plate 12 can be formed by processing one of these insulating materials into a plate shape.

The second metal plate 13 is joined to the front surface (second surface) of the first insulating plate 12. The second metal plate 13 is an electrically conductive plate for electrically connecting the semiconductor chip 15 to a terminal (not illustrated in FIG. 1). The second metal plate 13 can be formed by processing copper into a plate shape, for example. A circuit pattern for connecting various electrodes provided on the semiconductor chip 15 to corresponding terminals, respectively, is formed on the second metal plate 13.

The first joining material 14 is provided between the second metal plate 13 and the semiconductor chip 15. For example, a solder material or a sintered material can be used as the first joining material 14. The sintered material contains silver or copper, for example. When the first joining material 14 is a sintered material, thermal resistance can be reduced.

The semiconductor chip 15 is joined to the second metal plate 13 with the first joining material 14. The semiconductor chip 15 includes a semiconductor element containing a compound semiconductor such as SiC (silicon carbide). Examples of the semiconductor element using SiC include a MOSFET and an IGBT.

In a case where the above semiconductor element is a MOSFET, the drain electrode is formed on the back surface side of the semiconductor chip 15. On the other hand, the source electrode and the gate electrode are formed on the front surface side of the semiconductor chip 15. In a case where the above semiconductor element is an IGBT, the collector electrode is formed on the back surface side of the semiconductor chip 15. On the other hand, the emitter electrode and the gate electrode are formed on the front surface side of the semiconductor chip 15.

One end of the bonding wire 16 is joined to the source electrode of the semiconductor chip 15 (the emitter electrode in a case where the semiconductor chip 15 is an IGBT) or the gate electrode thereof. The other end of the bonding wire 16 is joined to the second metal plate 13. The bonding wire 16 is made of aluminum, for example, and is joined to the semiconductor chip 15 and the second metal plate 13 by ultrasonic joining.

Although only one bonding wire 16 is illustrated in FIG. 1, the number of bonding wires 16 is not limited to any specific number. Further, the semiconductor chip 15 may be electrically connected to the second metal plate 13 by ribbon bonding in place of the bonding wire 16.

The resin member 17 encapsulates the semiconductor chip 15 and the bonding wire 16. The resin member 17 is mold resin.

Assuming that many semiconductor chips 15 are mounted on one first insulating plate 12 in the semiconductor device 1 configured in the manner described above, if even one defect occurs in an electrical test process for inspecting the electrical characteristics of the semiconductor chips 15, a non-defective semiconductor chip 15 is also treated as a defective product. In this case, the yield decreases.

Meanwhile, in the semiconductor device 1 according to the present embodiment, the number of semiconductor chips 15 mounted on one first insulating plate 12 is only one. Therefore, it is possible to avoid the non-defective semiconductor chip 15 from being treated as a defective product. Accordingly, the yield can be improved.

### Second Embodiment

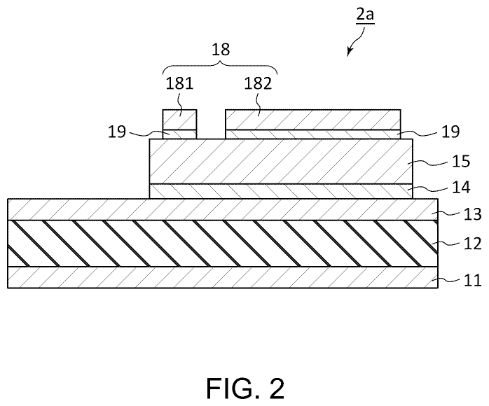

FIG. 2 is a cross-sectional view illustrating a schematic configuration of a semiconductor device according to a second embodiment. Constituent elements identical to those of the first embodiment described above are denoted by like reference characters and detailed explanations thereof are omitted.

In a semiconductor device 2a illustrated in FIG. 2, a third metal plate 18 is joined to the front surface of the semiconductor chip 15 with a second joining material 19. The third metal plate 18 is formed by a copper plate, similarly to the first metal plate 11 and the second metal plate 13 described in the first embodiment. The second joining material 19 is formed by a solder material or a sintered material, similarly to the first joining material 14.

The third metal plate 18 has a first portion 181 and a second portion 182. The first portion 181 is electrically connected to the gate electrode of the semiconductor chip 15. Meanwhile, the second portion 182 is electrically connected to the emitter electrode or the source electrode of the semiconductor chip 15.

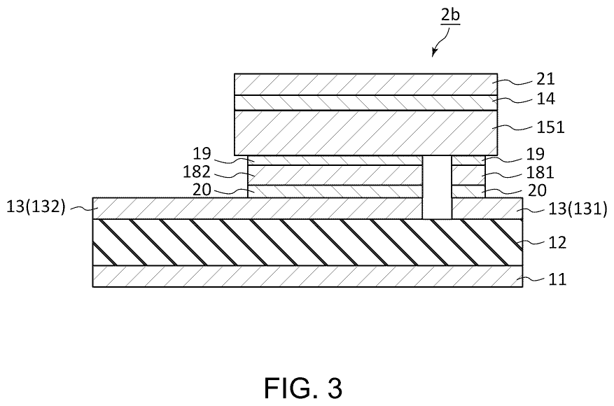

FIG. 3 is a cross-sectional view illustrating a schematic configuration of a semiconductor device according to a modification of the second embodiment. In a semiconductor device 2b illustrated in FIG. 3, a semiconductor chip 151 is provided in place of the semiconductor chip 15. The semiconductor chip 151 is a flip chip. That is, the semiconductor chip 151 is obtained by inverting the semiconductor chip 15 illustrated in FIG. 2 by 180 degrees with respect to the first insulating plate 12. Therefore, the source electrode (the emitter electrode in a case where the semiconductor chip 151 is an IGBT) and the gate electrode are arranged on the back surface side of the semiconductor chip 151, and the drain electrode (the collector electrode in a case where the semiconductor chip 151 is an IGBT) is arranged on the front surface side of the semiconductor chip 151.

In addition, in the semiconductor device 2b according to the present modification, the first portion 181 of the third metal plate 18 is joined to a third portion 131 of the second metal plate 13 with a third joining material 20. The second portion 182 of the third metal plate 18 is joined to a fourth portion 132 of the second metal plate 13 with the third joining material 20. The third joining material 20 is formed by a solder material or a sintered material, similarly to the first joining material 14 and the second joining material 19.

In the present modification, it is preferable that the thickness of the third metal plate 18 is within a range of 50 to 200 μm in order to function as a stress relaxation layer. The thickness of the third joining material 20 is thinner than the third metal plate 18. However, when the third joining material 20 is too thin, the third metal plate 18 and the second metal plate 13 may be joined to each other insufficiently. Therefore, the thickness of the third joining material 20 is preferably within a range of 20 to 40 μm.

Further, in the semiconductor device 2b according to the present modification, a fourth metal plate 21 is joined to the front surface of the semiconductor chip 151 with the first joining material 14. The fourth metal plate 21 is a copper plate, similarly to the other metal plates. The fourth metal plate 21 is electrically connected to the drain electrode of the semiconductor chip 151 (the collector electrode in a case where the semiconductor chip 151 is an IGBT).

In the semiconductor device 2a according to the present embodiment described above, the number of semiconductor chips 15 mounted on the first insulating plate 12 is only one. In the semiconductor device 2b according to the present modification, the number of semiconductor chips 151 mounted on the first insulating plate 12 is only one. Therefore, also in the present embodiment, it is possible to avoid a non-defective semiconductor chip from being treated as a defective product. Accordingly, the yield can be improved.

### Third Embodiment

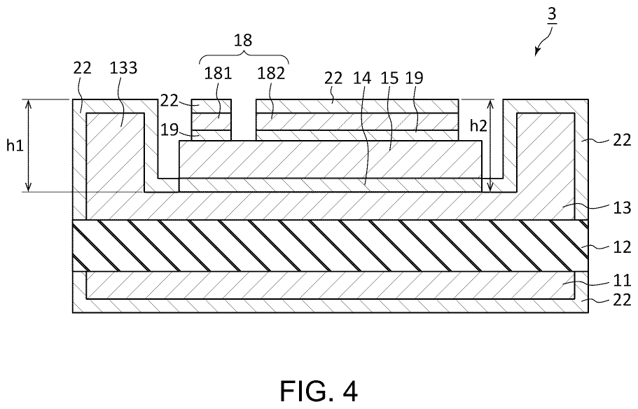

FIG. 4 is a cross-sectional view illustrating a schematic configuration of a semiconductor device according to a third embodiment. Constituent elements identical to those of the first and second embodiments described above are denoted by like reference characters and detailed explanations thereof are omitted.

In a semiconductor device 3 illustrated in FIG. 4, a first concave portion 133 is formed in an upper portion of the second metal plate 13. The semiconductor chip 15 is arranged in the first concave portion 133. In addition, in the semiconductor device 3 according to the present embodiment, a plating layer 22 is formed on a surface of each of the first metal plate 11, the second metal plate 13, and the third metal plate 18.

The plating layer 22 can be formed by electroless plating, for example. In the present embodiment, a planarization process is performed for the plating layer 22 after electroless plating. In this planarization process, the plating layer 22 is ground in such a manner that a height h1 from the bottom of the first concave portion 133 to the plating layer 22 formed on the upper end of the first concave portion 133 and a height h2 from the bottom of the first concave portion 133 to the plating layer 22 formed on the upper surface of the third metal plate 18 are equal to each other. With this planarization process, three wires respectively connected to the gate electrode, the drain electrode (the collector electrode in a case where the semiconductor chip 15 is an IGBT), and the emitter electrode (the source electrode) can be formed in the same wiring layer.

In the present embodiment described above, the number of semiconductor chips 15 mounted on the first insulating plate 12 is only one. Therefore, as in the first and second embodiments described above, it is possible to avoid a non-defective semiconductor chip 15 from being treated as a defective product. Accordingly, the yield can be improved.

### Fourth Embodiment

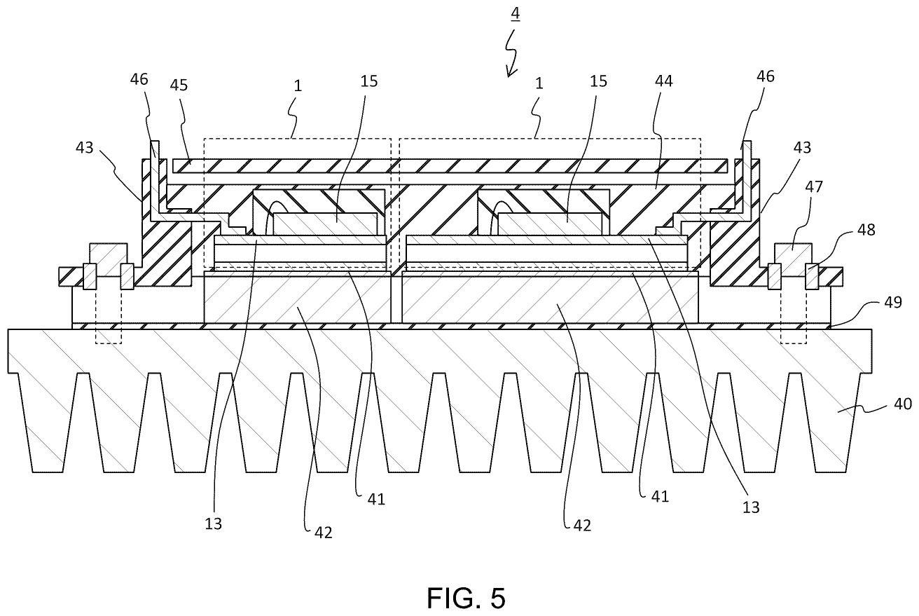

FIG. 5 is a cross-sectional view illustrating a schematic configuration of a semiconductor device according to a fourth embodiment. A semiconductor device 4 illustrated in FIG. 5 is a case-type power module in which the semiconductor devices 1 described in the first embodiment are accommodated in a case 43.

In the present embodiment, each semiconductor device 1 is joined to a base material 42 with a fourth joining material 41 individually. That is, the semiconductor device 4 is provided with the same number of base materials 42 as the semiconductor devices 1. The fourth joining material 41 is a solder material, for example. The base material 42 functions as a heat-dissipation plate for dissipating heat generated in the semiconductor chip 15 of the semiconductor device 1. The base material 42 contains copper or aluminum, for example.

In the semiconductor device 4 according to the present embodiment, each semiconductor device 1 is individually placed on the base material 42. That is, the base material 42 is provided for each semiconductor device 1. The back surface of the base material 42 is exposed from the case 43. The case 43 is made of resin, for example.

The case 43 is fixed to a heat-dissipation fin 40 with a screw 47 and a washer 48. A grease material 49 is applied between the case 43 and the heat-dissipation fin 40. The grease material 49 fills the gap formed between the case 43 and the heat-dissipation fin 40, and thus heat generated in the semiconductor chip 15 can be efficiently transmitted to the heat-dissipation fin 40.

In addition, the case 43 is filled with an encapsulation material 44. As the encapsulation material 44, a transparent gel is used, for example. An upper-end opening of the case 43 is sealed by a lid 45. Accordingly, each semiconductor device 1 is encapsulated in the case 43.

The case 43 is further provided with a terminal 46. One end of the terminal 46 is joined to the second metal plate 13 of each semiconductor device 1. The other end of the terminal 46 is exposed to outside of the case 43.

In a case where the semiconductor device 4 is mounted in a power converter such as an inverter, power converted from direct current to alternating current by a switching operation of each semiconductor chip 15 is supplied to a load, for example, a motor, connected to the other end of the terminal 46. The terminal 46 can function as a power terminal in this manner.

The one end of the terminal 46 may be connected to the gate electrode of the semiconductor chip 15. In this case, the other end of the terminal 46 is connected to a gate drive circuit (not illustrated). The gate drive circuit generates a control signal turning on and off the semiconductor chip 15. This control signal controls the switching operation of the semiconductor chip 15. Accordingly, the terminal 46 can also function as a signal terminal.

In the present embodiment described above, one power module is configured by incorporating the semiconductor devices 1 therein. In each incorporated semiconductor device 1, the number of semiconductor chips 15 mounted on one first insulating plate 12 is only one. Therefore, it is possible to avoid the non-defective semiconductor chip 15 from being treated as a defective product before the semiconductor devices 1 are incorporated into the power module. Therefore, the yield can be improved also in the present embodiment.

### Fifth Embodiment

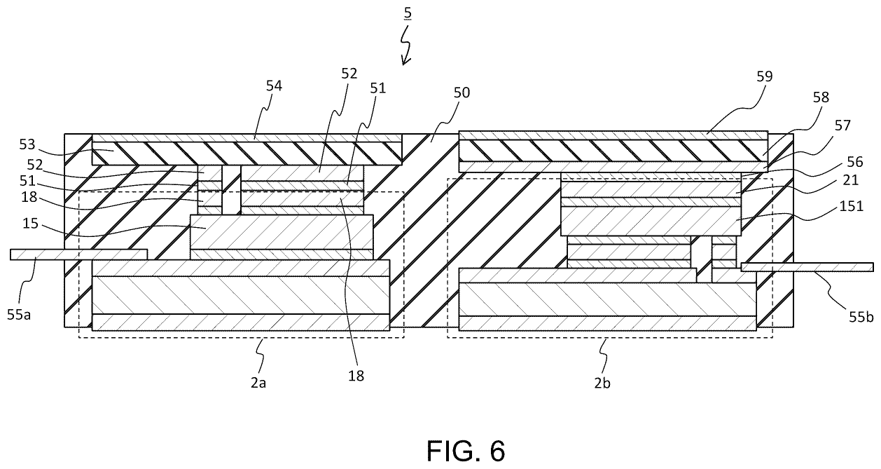

FIG. 6 is a cross-sectional view illustrating a schematic configuration of a semiconductor device according to a fifth embodiment. A semiconductor device 5 illustrated in FIG. 6 is a double-sided cooling power module that dissipates heat from both surfaces of the semiconductor chip 15 and the semiconductor chip 151 described in the second embodiment.

In the present embodiment, the semiconductor device 2a and the semiconductor device 2b are encapsulated with a resin member 50. The resin member 50 is mold resin, for example. In the resin member 50, the third metal plate 18 of the semiconductor device 2a is joined to a seventh metal plate 52 with a fifth joining material 51. The fifth joining material 51 is a solder material, for example. The seventh metal plate 52 is a copper plate, for example.

The seventh metal plate 52 is joined to the back surface of a third insulating plate 53. The third insulating plate 53 contains an insulating material such as silicon nitride (SiN), aluminum nitride (AlN), and aluminum oxide (Al₂O₃), similarly to the first insulating plate 12. An eighth metal plate 54 is joined to the front surface of the third insulating plate 53. An upper surface of the eighth metal plate 54 is exposed from the resin member 50. The eighth metal plate 54 is a copper plate, for example.

In the semiconductor device 2a according to the present embodiment, heat generated on the front surface side of the semiconductor chip 15 is transmitted through the seventh metal plate 52 and the third insulating plate 53 and is finally dissipated from the eighth metal plate 54.

In the resin member 50, the fourth metal plate 21 of the semiconductor device 2b is joined to a fifth metal plate 57 with a sixth joining material 56. The sixth joining material 56 is a solder material, for example. The fifth metal plate 57 is a copper plate, for example.

The fifth metal plate 57 is joined to the back surface of a second insulating plate 58. The second insulating plate 58 contains an insulating material such as silicon nitride (SiN), aluminum nitride (AlN), and aluminum oxide (Al₂O₃), similarly to the first insulating plate 12. A sixth metal plate 59 is joined to the front surface of the second insulating plate 58. The upper surface of the sixth metal plate 59 is exposed from the resin member 50. The sixth metal plate 59 is a copper plate, for example.

In the semiconductor device 2b according to the present embodiment, heat generated on the front surface side of the semiconductor chip 151 is transmitted through the fifth metal plate 57 and the second insulating plate 58 and is finally dissipated from the sixth metal plate 59.

In the semiconductor device 5 according to the present embodiment, a terminal 55a is joined to the second metal plate 13 of the semiconductor device 2a. The terminal 55a can function as a power terminal electrically connected to the drain electrode of the semiconductor chip 15 (the collector electrode in a case where the semiconductor chip 15 is an IGBT). A terminal 55b is joined to the third portion 131 of the second metal plate 13 of the semiconductor device 2b. The terminal 55b can function as a signal terminal electrically connected to the gate electrode of the semiconductor chip 151.

In the present embodiment described above, one power module is configured by incorporating the semiconductor device 2a and the semiconductor device 2b therein. In each of the incorporated semiconductor devices 2a and 2b, the number of semiconductor chips 15 or 151 mounted on one first insulating plate 12 is only one. Therefore, it is possible to avoid a non-defective semiconductor chip 15 and a non-defective semiconductor chip 151 from being treated as a defective product before the semiconductor device 2a and the semiconductor device 2b are incorporated into the power module. Accordingly, the yield can be improved also in the present embodiment.

### Sixth Embodiment

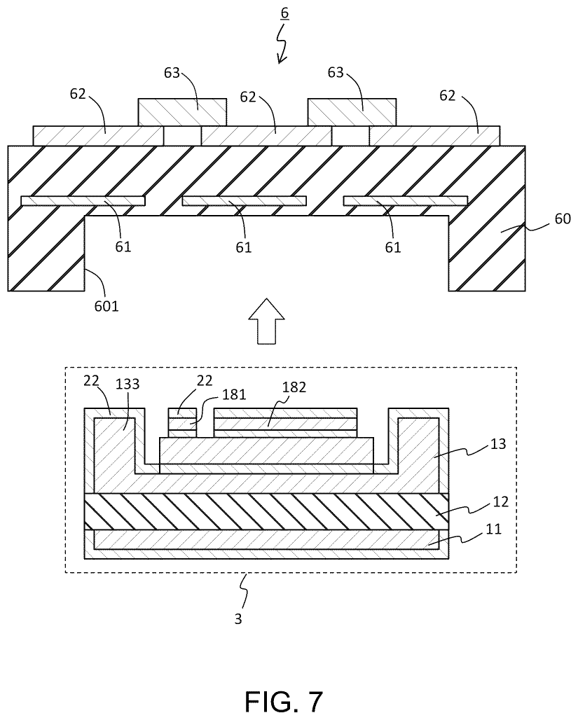

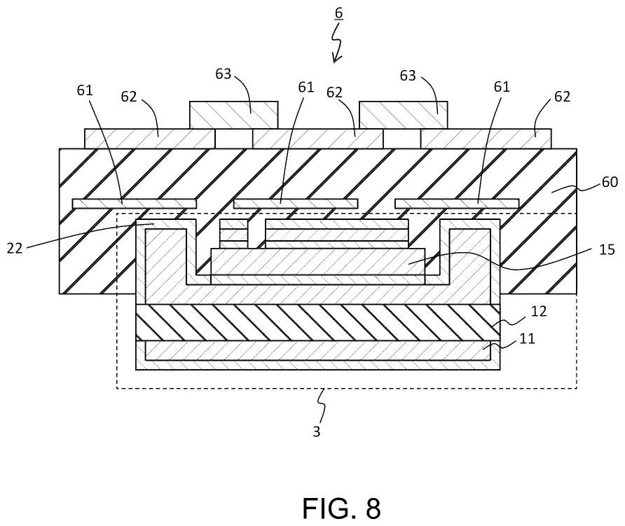

FIG. 7 is a cross-sectional view illustrating a disassembled configuration of a semiconductor device according to a sixth embodiment. FIG. 8 is a cross-sectional view illustrating a schematic configuration of the semiconductor device according to the sixth embodiment. A semiconductor device 6 illustrated in FIGS. 7 and 8 is a power module having component-incorporated PCB structure in which the a semiconductor device 3 described in the third embodiment is embedded in a printed circuit board 60. Although only one semiconductor device 3 is embedded in the printed circuit board 60 in FIGS. 7 and 8, it suffices that the number of semiconductor devices 3 is at least one.

In the semiconductor device 6 according to the present embodiment, the printed circuit board 60 is formed by using epoxy resin. A second concave portion 601 is provided in a lower portion of the printed circuit board 60 as illustrated in FIG. 7. The semiconductor device 3 is embedded in the second concave portion 601. At this time, as illustrated in FIG. 8, a portion of the semiconductor device 3 is embedded in the second concave portion 601. For example, in order to avoid deterioration of the heat dissipation characteristics while ensuring the sealing property of the semiconductor chip 15, the semiconductor chip 15, the second metal plate 13, and the third metal plate 18 are arranged in the second concave portion 601, and the first metal plate 11 and the first insulating plate 12 are exposed from the second concave portion 601.

A plurality of wires 61 are provided in the printed circuit board 60. Each wire 61 is formed by a plated metal wire, for example. The wires 61 are connected to the gate electrode of the semiconductor chip 15, the drain electrode (the collector electrode in a case where the semiconductor chip 15 is an IGBT), and the source electrode (the emitter electrode in a case where the semiconductor chip 15 is an IGBT), respectively.

In the semiconductor device 3, as described in the third embodiment, the height h1 from the bottom of the first concave portion 133 to the plating layer 22 formed on the upper end of the first concave portion 133 and the height h2 from the bottom of the first concave portion 133 to the plating layer 22 formed on the upper surface of the third metal plate 18 are equal to each other. Therefore, the wires 61 connected to the respective electrodes of the semiconductor chip 15 can be formed in the same wiring layer. Accordingly, electrical loss and thermal loss generated in the wires 61 can be reduced. Although the plating layer 22 is not connected to the wires 61 in FIG. 8, they are connected to each other via contact plugs (not illustrated), for example.

In the semiconductor device 6 according to the present embodiment, pads 62 are formed on an upper portion of the printed circuit board 60. Electronic components 63 are mounted on the pads 62. The pads 62 are formed by copper foil, for example. The electronic components 63 include a passive component such as a capacitor and a coil, and an active component such as an LSI (Large Scale Integration). The passive component is used in a circuit element such as a DC-DC converter. The active component is used in a gate driver circuit of the semiconductor chip 15, for example.

In the present embodiment described above, one power module is configured by embedding at least one semiconductor device 3 in the printed circuit board 60. In the embedded semiconductor device 3, the number of semiconductor chips 15 mounted on one first insulating plate 12 is only one. Therefore, it is possible to avoid the non-defective semiconductor chip 15 from being treated as a defective product before the semiconductor device 3 is embedded in the printed circuit board 60. Accordingly, the yield can be improved also in the present embodiment.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

1. A semiconductor device comprising:
a first insulating plate;
a first metal plate provided on a first surface of the first insulating plate;
a second metal plate provided on a second surface of the first insulating plate opposite the first surface;
a semiconductor chip provided on the second metal plate; and
a resin member encapsulating the semiconductor chip, wherein
the number of semiconductor chips provided on the second metal plate is only one.

2. The device of claim 1, further comprising a bonding wire joined to the semiconductor chip at one end and to the second metal plate at the other end, wherein
the bonding wire is encapsulated with the resin member, together with the semiconductor chip.

3. The device of claim 1, further comprising a third metal plate provided on the semiconductor chip, wherein
the third metal plate is encapsulated with the resin member, together with the semiconductor chip.

4. The device of claim 1, wherein the semiconductor chip is a flip chip, and
the device further comprises:
a third metal plate provided between the flip chip and the second metal plate; and
a joining material provided between the second metal plate and the third metal plate.

5. The device of claim 4, wherein
a thickness of the third metal plate is within a range of 50 to 200 μm, and
a thickness of the joining material is within a range of 20 to 40 μm.

6. The device of claim 1, wherein
a first concave portion in which the semiconductor chip is arranged is provided in an upper portion of the second metal plate, and
the device further comprises:
a third metal plate provided on the semiconductor chip; and
a plating layer provided on each of an upper end of the first concave portion and an upper surface of the third metal plate.

7. The device of claim 6, wherein a height from a bottom of the first concave portion to the plating layer provided on the upper end of the first concave portion is equal to a height from the bottom to the plating layer provided on the upper surface of the third metal plate.

8. The device of claim 2, further comprising:
a case accommodating a plurality of the semiconductor devices; and
a plurality of base materials provided for the respective semiconductor devices.

9. The device of claim 4, further comprising:
a fourth metal plate provided on the flip chip;
a fifth metal plate joined to the fourth metal plate;
a second insulating plate provided on the fifth metal plate; and
a sixth metal plate provided on the second insulating plate.

10. The device of claim 6, wherein
the resin member is a printed circuit board, and a second concave portion in which the semiconductor chip, the second metal plate, and the third metal plate are arranged is provided at a bottom of the printed circuit board, and
the device further comprises an electronic component provided on an upper portion of the printed circuit board.

11. The device of claim 1, further comprising a first joining material provided between the second metal plate and the semiconductor chip, wherein
the first joining material is a solder material or a sintered material.

12. The device of claim 11, wherein the sintered material contains silver or copper.

13. The device of claim 3, further comprising a second joining material provided between the third metal plate and the semiconductor chip, wherein
the second joining material is a solder material or a sintered material.

14. The device of claim 13, wherein the sintered material contains silver or copper.

15. The device of claim 3, wherein the third metal plate has a first portion and a second portion apart from the first portion on a front surface of the semiconductor chip.

16. The device of claim 15, wherein the second metal plate has a third portion to be joined to the first portion of the third metal plate and a fourth portion to be joined to the second portion of the third metal plate.

17. The device of claim 1, wherein an insulating material contained in the first insulating substrate is silicon nitride (SiN), aluminum nitride (AlN), or aluminum oxide (Al₂O₃).

18. The device of claim 1, wherein the first metal plate and the second metal plate are copper plates.

19. The device of claim 1, wherein the resin member is mold resin.

20. The device of claim 1, wherein the semiconductor chip includes a MOSFET or an IGBT.
